(19) United States
(12) Patent Application Publication
(10) Pub. No.: US 2025/0320665 A1
(43) Pub. Date: Oct. 16, 2025

(54) PROCESSES FOR METALLIZATION AND PRODUCTS FORMED THEREFROM

(71) Applicant: MELODEA LTD., Rehovot (IL)

(72) Inventors: Clarite AZERRAF, Ashdod (IL); Yuval NEVO, Yavne (IL); Einav BARAK-KULBAK, Kibbutz Tzora (IL); Rinat ELIYAHU, Kibbutz Kiryat Anavim (IL); David Michael LEIBLER, Tel-Aviv (IL); Yaniv NEVO, Ness Ziona (IL)

(73) Assignee: MELODEA LTD., Rehovot (IL)

(21) Appl. No.: 18/569,437

(22) PCT Filed: Jun. 14, 2022
(86) PCT No.: PCT/IL2022/050636

§ 371 Date: Dec. 12, 2023

Related U.S. Application Data
(60) Provisional application No. 63/202,495, filed on Jun. 14, 2021.
(60) Provisional application No. 63/262,849, filed on Oct. 21, 2021.

(51) Int. Cl. D21H 19/84; B65D 65/42; C09D 7/65; C09D 103/02; C09D 121/02; C09D 129/04; C09D 191/06; D21H 19/08; D21H 19/12

(52) U.S. Cl. CPC D21H 19/84; B65D 65/42; C09D 7/65; C09D 103/02; C09D 121/02; C09D 129/04; C09D 191/06; D21H 19/08; D21H 19/12; B65D 2565/387

(57) ABSTRACT

The technology disclosed herein concerns films and products providing superior OTR and WVTR properties.

### TECHNOLOGICAL FIELD

The invention generally contemplates provision of metalized surfaces and uses thereof.

### BACKGROUND OF THE INVENTION

Metallized packaging materials provide excellent barrier properties and are therefore widely used in food packaging applications. They are used in different packaging forms, as enclosures for liquid and solid materials, and as protective enclosures for drugs and cosmetic compositions. However, despite their extensive use, known barrier properties have not been ideal.

Typically, metalized surfaces are formed by metal lamination or foiling or the surface [1]. Vapor deposition methods are also known. However, these did not yield improved barrier properties.

### BACKGROUND PUBLICATIONS

[1] DE 20 2018 103 076.0

### GENERAL DESCRIPTION

The technology subject of the present application is based on the finding that films formed of specific material blends comprising one or more cellulose nanomaterials, such as cellulose nanocrystals (CNC), or at least one wax material, vapor-deposited with a metal thin film, demonstrate highly superior oxygen transmission rate (OTR) and water vapor transmission rate (WVTR) as compared to metalized or non-metalized surfaces of the art known to have superior OTR and WVTR properties. Comparison of oxygen barrier properties, OTR, at 70% RH and 23° C., and water vapor barrier properties, WVTR, at 90% RT and 38° C., demonstrated OTR values around or below 1 ml/m²·day and WVTR values around or below 5 gr/m²·day for metalized surfaces of the invention—values that are hundreds or thousand times better than for those measured on:
non-metalized surfaces,
surfaces that do not have a cellulose material, e.g., CNC, or a wax material directly in contact with the deposited metal, and/or
metalized surfaces formed by deposition methods other than vapor deposition.

As vapor deposition allows for the formation of certain metal thin films of varying thinness and porosity or pore density, metalized films having specific compositions and properties have been developed.

The inventors thus provide a provision of metalized material blend films, namely, films composed of or derived from material blends that have been metalized with a thin film. As will be further detailed herein below, the dry film derived from a material combination or a material blend comprises the same materials as in the material blend from which it is derived. Thus, within the context of the present invention, a film of composed of a material blend is a film which comprises or consists the combination of materials defined for the particular blend. Similarly, a film derived from a material blend is a film which was formed by a particular formulation or combination of materials.

Films of the invention may comprise a film of a material blend, a thin film of a metal and optionally a substrate. In some configurations, metalized products of the invention include:
a metalized material blend film consisting of a film of a material blend and film of at least one metal provided on (or in association, or in contact, or on the surface of) the film of the material blend:
a metalized material blend film consisting of a film of a material blend, a film of at least one metal and a substrate, wherein the film is provided on (or in association, or in contact, or on the surface of) the film of the material blend and wherein the substrate is provided on the surface of the film of the material blend or on the film of the at least one metal:
a metalized material blend film comprising of a film of a material blend and film of at least one metal provided on (or in association, or in contact, or on the surface of) the film of the material blend:
a metalized material blend film comprising of a film of a material blend, a film of at least one metal and a substrate, wherein the film is provided on (or in association, or in contact, or on the surface of) the film of the material blend and wherein the substrate is provided on the surface of the film of the material blend or on the film of the at least one metal: and
other, as disclosed herein.

As used herein, the term “material blend” refers to a material composition or a mixture of components constituting a main film of a metalized product that is optionally formed on a substrate and associated with a metal film via a metallization process that may comprise or involve vapor deposition. The material blend is a homogenous mixture comprising two or more materials, one of which may be a cellulose material and/or a wax material and the other materials may be additives that together with the cellulose material and/or wax impart to the film, when metalized, with superior OTR and/or WVTR properties. In some configurations, the material blend is free of or excludes metallic materials, wherein optionally the metal is a zero-valent metal atom. In some configurations, however, the material blend may comprise a metallic material consisting metallic nanoparticles, as disclosed herein.

Films or products of the invention may generally be structured of two, three or more layered or stacked component regions: a film of a material blend, a metalized surface formed of a metal and optionally a substrate. Typically, the film of the material blend is a continuous solid film in which the components of the blend are homogenously distributed. In metalized products of the invention, the specific components or materials making up the blend, do not themselves constitute separate material films or layers, nor are distributed in separate regions of the film composed or formed of the material blend.

In a first aspect there is provided a metalized material film, wherein the metalized film comprises or consists a film of a material blend, a metal surface and optionally a substrate, wherein the material blend film comprises at least one cellulose material and/or at least one wax and one or more additional additives.

In some embodiments, the material blend comprises at least one cellulose material.

In some embodiments, the material blend comprises at least one wax.

In some embodiments, the material blend comprises at least one cellulose material and at least one wax material.

In some embodiments, the metal surface is a metal film formed by vapor deposition.

In some embodiments, the invention provides any one of the following:
a vapor-deposited metalized film comprising or consisting a film of a material blend comprising a cellulose material, and a metal surface:
a vapor-deposited metalized film, comprising or consisting a film of a material blend comprising a cellulose material, a metal surface and a substrate:
a vapor-deposited metalized film, comprising or consisting a film of a material blend comprising a wax material and a metal surface:
a vapor-deposited metalized film comprising or consisting a film of a material blend comprising a wax material, a metal surface and a substrate:
a vapor-deposited metalized film, comprising or consisting a film of a material blend comprising a cellulose material and a wax material and a metal surface:
a vapor-deposited metalized film, comprising or consisting a film of a material blend comprising a cellulose material and a wax material, a metal surface and a substrate.

Also provided is a vapor-deposited metalized cellulose nanocrystalline (CNC)-based film, wherein the metalized CNC-based film consisting a CNC-based film, a metallized surface and optionally a substrate.

The invention also provides a surface coated or associated with a metalized film of a material blend, wherein metallization is achievable by vapor deposition.

Also provided is a metalized film of a material blend, wherein metallization is by vapor-depositing a metal thin film on a surface of said film of the material blend.

In other configurations, there is provided a metalized cellulose material-based film, the film comprises a cellulose material, wherein the film is layered with a thin metal film, wherein the thin metal film having a thickness of between 500 Å (Angstrom) and 100 nm.

Further configurations provide a metalized wax-based film, the film comprises a wax material, wherein the film is layered with a thin metal film, wherein the thin metal film having a thickness of between 500 Å (Angstrom) and 100 nm.

Yet in other configurations provided is a metalized film comprising cellulose material and wax material (i.e., the film comprises the at least one cellulose material and the at least one wax material), wherein the film is layered with a thin metal film, wherein the thin metal film having a thickness of between 500 Å (Angstrom) and 100 nm.

The metalized products may be provided on a substrate, wherein the substrate is on either a face of the film of the material blend or the face of the metal film. In other words, the metalized product may be provided in a “direct configuration”, wherein the film of a material blend is positioned between a substrate and a metalized surface (substrate/blend/metal): or in an “inverse configuration”, wherein the substrate is on the metalized surface (blend/metal/substrate). In either configuration, films of the invention are provided with the metal in direct contact with the material blend. As used herein, the term “contact”, when in reference to the association of or interaction between the metal film and the film of the material blend, means layering of one film on a face region of the other, typically complete surface, such that a stacked structure is formed. In some configurations, the contact is an intimate contact that does not involve any intermediating materials or films (thus-direct contact), and which permits a secure un-peelable association. Without wishing to be bod by theory or mechanism, the association is believed not to be chemical but rather intercalation or penetration or physical anchoring on the metal layer into pores of generally the layer of the blend material.

As noted herein, metallization of a film of a material blend may be achievable by vapor deposition of a metal, such as aluminum, or by any known metallization process. Where vapor deposition is employed. it may be direct or indirect. In a direct vapor deposition process, the metal is vapor deposited directly on a film of a material blend. In an indirect vapor deposition process, the metal is vapor deposited on a sacrificial film or substrate and is then transferred onto the film of a material blend. The “metallization” thus encompasses metal deposition on a film of the material blend. Metallization, as used herein, is by no means lamination, foiling or coating of the film of the material blend with a metal. Metal deposition consists vapor deposition, as detailed herein.

“Vapor deposition” or “physical vapor deposition”, PVD, is one of a variety of vacuum deposition methods that can be used to produce metalized films or products. Physical vapor deposition is characterized by a process in which the material goes from a condensed phase to a vapor phase and then back to a thin film condensed phase. The physical vapor deposition processes may be sputtering or evaporation. To achieve metallization, the following steps are typically followed: (i) sputtering/evaporation to produce a vapor phase: (ii) supersaturation of the vapor phase in an inert atmosphere to promote the condensation of metal nanoparticles: and (iii) consolidation of the nanocomposite by thermal treatment under inert atmosphere.

In a step of metallization, the substrate may be optionally surface treated before metallization to improve metal adhesion. Surface pre-treatment may be achievable by any method known in the art, such as plasma, corona discharge, and flame treatment. Pre-treatment, where present, does not involve material layering of a mediating material to separate between the substrate and the deposited metal. Such mediating films typically consisting of starch, PVOH, adhesive materials, and others are excluded. Additionally, where metal deposition is directly on a surface of a film of a material blend, no surface treatment may be employed.

Metallization may take place in a conventional metallizer, which comprises a chamber divided into two or more sections, which are atmosphere evacuated to a reduced pressure below atmospheric pressure. A reel or roll of the unmetallized film, e.g., of a blend material comprising a cellulose material and/or wax on a substrate, is provided in one of the two sections. The film to be metallized passes from the reel onto a roll which carries the film into the other section of the metallizer where metal, such as aluminum, is vaporized and deposited onto a surface of the film, usually as the film passes around the roll. Typically, the roll is cooled to between −15° C. and −35° C. After metallization is completed, the metallized film passes back into the first section of the metallizer where the metallized film is rolled back. The process may change depending, inter alia, on the size of the sheet to be coated and the material to be coated.

The “metal” may be any metallic material or an alloy thereof or a combination of two or more metals or metal forms (e.g., two different alloys of the same metal). The metal may be provided in a composite in a pure metallic form, in an oxide form, in a doped form, in an alloy form or as a mixture of metals, oxides or alloys of such metals. Generally speaking, the metal used is a metal that is nontoxic, and which does not leech out. Such metals include zinc, aluminum, iron, titanium, tin and others.

In some embodiments, the metal is aluminum.

In some embodiments, the metal region consists a single metal. In other embodiments, the metal is a mixture or a composition of one or more metals or metal oxides or alloys.

In some embodiments, the material to be deposited is a metalloid, such as a silicone.

The consolidation of the metal and/or silicone onto the material blend film surface affords a metalized product in a form of or comprising a film having an averaged thickness between 500 Å (Angstrom) and 500 nm or 100 nm. The actual thickness of the metal deposition film may be varied. The thickness may be between 500 Å and 100 nm, or between 500 Å and 95 nm, 500 Å and 90 nm, 500 Å and 85 nm, 500 Å and 80 nm, 500 Å and 75 nm, 500 Å and 70 nm, 500 Å and 65 nm, 500 Å and 60 nm, 500 Å and 55 nm, 500 Å and 50 nm, 500 Å and 45 nm, 500 Å and 40 nm, 500 Å and 35 nm, 500 Å and 30 nm, 500 Å and 25 nm, 500 Å and 20 nm, 500 Å and 15 nm, 500 Å and 10 nm, 500 Å and 5 nm, 500 Å and 4 nm, 500 Å and 3 nm, 500 Å and 2 nm, 500 Å and 1 nm, 1 and 100 nm, 5 and 100 nm, 10 and 100 nm, 20 and 100 nm, 30 and 100 nm, 40 and 100 nm, 50 and 100 nm, 60 and 100 nm, 70 and 100 nm, 80 and 100 nm or between 90 and 100 nm.

In some embodiments, a metalized film is fabricated by vapor deposition. Accordingly, a fabrication method which may involve vapor-depositing a metal on a surface of said material blend film may comprise (i) vapor-depositing a metal on a surface of a film, wherein the film is provided on a substrate (direct vapor deposition), or (ii) vapor-depositing a metal on a substrate to obtain a metalized surface on said substrate and transferring said metal film onto a film of the material blend (indirect vapor deposition).

In some embodiments, the method comprises obtaining a material blend film on a substrate.

The film of the material blend may be of various thicknesses. Typically, its thickness is between 0.5 and 20 μm. in some embodiments, the thickness is between 0.5 and 19 μm, 0.5 and 18 μm, 0.5 and 17 μm, 0.5 and 16 μm, 0.5 and 15 μm, 0.5 and 14 μm, 0.5 and 13 μm, 0.5 and 12 μm, 0.5 and 11 μm, 0.5 and 10 μm, 0.5 and 9 μm, 0.5 and 8 μm, 0.5 and 7 μm, 0.5 and 6 μm, 0.5 and 5 μm, 0.5 and 4 μm, 0.5 and 3 μm, 0.5 and 2 μm, 0.5 and lum, 5 and 20 μm, 5 and 10 μm, 10 and 20 μm, 15 and 20 μm, 1 and 5 μm, 1 and 10 μm, 1 and 15 μm, or between 1 and 20 μm.

In some embodiments, the film of a material blend is formed by applying a material blend or a suspension consisting or comprising same on a substrate using coating techniques such as rod coater, gravure, flexographic printing, blade coater, slot die and more, followed by drying of the wet coating for formation of a dry coated layer upon the substrate. The self-standing films of the material blend(s) are formed using methods such as casting and drying, coating and separation, etc., of a suspension consisting or comprising a material blend.

In some embodiments, the film of the material blend consists or comprises a material composition as defined. Where additives are present, they may be selected from carbohydrates, crosslinking agents, polymers, natural additives, minerals, surfactants, nanoparticles and others.

In some embodiments, the additive is at least one carbohydrate, optionally selected from starch, dextrin, cyclodextrin, maltodextrin, pectin, hemicellulose, sorbitol, glycogen and others.

In some embodiments, the additive is at least one crosslinking agent, optionally selected from poly acrylic acid (PAA), polyethyleneimine (PEI), polyurethanes, alkenyl succinic anhydride (ASA), alkyl ketene dimer (AKD) and others.

In some embodiments, the additive is at least one polymer, optionally selected from polyvinyl alcohol (PVOH), polyvinyl acetate (PVAc), ethylene vinyl alcohol (EVOH), polyvinyl pyrrolidone (PVP), ethylene vinyl acetate (EVA), latex, acrylic polymer, thermoplastic polymer, epoxides, polyolefin polymers and others.

In some embodiments, the additive is a natural additive, such as lignin, protein, chitosan, amino acid, lipid, gelatin, alginate and others.

In some embodiments, the additive is at least one mineral material, optionally selected from clay, talc, gypsum, calcite, kaolin, aluminum silicate, illite, vermiculite, smectite, chlorite, halloysite and others.

In some embodiments, the additive is at least one surfactant, optionally selected from anionic surfactants, cationic surfactants, zwitterionic surfactants, non-ionic surfactants, sulfate based-surfactants, sulfonate based-surfactants, phosphate based-surfactants, carboxylate based-surfactants, anti-foam materials (such as silicone based surfactants or organic based surfactants), ethoxylates based-surfactants, fatty acid ester based-surfactants, glycerol based-surfactants, sorbitol based-surfactants, alkyl polyglycoside and others. In some embodiments, the at least one surfactant may be selected from sodium dodecyl sulfate (SDS), sodium laureth sulfate (SLS), cetrimonium bromide (CTAB), cetylpyridinium chloride (CPC), benzalkonium chloride (BAC), benzethonium chloride (BZT), and dimethyldioctadecy lammonium bromide (DODAB).

In some embodiments, the additive is at least one type of nanoparticles, such as SiO₂, ZnO, TiO₂, Ag, Au, carbon, Al₂O₃, Fe and others.

In some embodiments, the additive is one or more additives selected as herein. In some embodiments, the additive is two or more additives, wherein each additive is selected from a different group of additives, i.e., carbohydrates, crosslinking agents, polymers, natural additives, minerals, surfactants and/or nanoparticles.

In some embodiments, the blend comprises at least one additive that is a carbohydrate, or a crosslinking agent, or a polymer, or a natural additive, or a mineral, or a surfactant, or a nanoparticle type.

In some embodiments, the blend comprises an additive that is a carbohydrate or a polymer or a crosslinking agent, each selected independently, as above.

In some embodiments, the additive is at least one carbohydrate, optionally selected from starch, dextrin, cyclodextrin, maltodextrin, pectin, hemicellulose, sorbitol, glycogen and others.

In some embodiments, the additive is poly acrylic acid (PAA).

In some embodiments, the additive is polyethyleneimine (PEI).

In some embodiments, the additive is a polyurethane.

In some embodiments, the additive is alkenyl succinic anhydride (ASA).

In some embodiments, the additive is alkyl ketene dimer (AKD).

In some embodiments, the additive is polyvinyl alcohol (PVOH).

In some embodiments, the additive is polyvinyl acetate (PVAc).

In some embodiments, the additive is ethylene vinyl alcohol (EVOH).

In some embodiments, the additive is polyvinyl pyrrolidone (PVP).

In some embodiments, the additive is ethylene vinyl acetate (EVA).

In some embodiments, the additive is latex.

In some embodiments, the additive is acrylic polymer.

In some embodiments, the additive is a thermoplastic polymer.

In some embodiments, the additive is an epoxide.

In some embodiments, the additive is a polyolefin.

In some embodiments, the additive is polyvinyl alcohol (PVOH), polyvinyl acetate (PVAc), ethylene vinyl alcohol (EVOH), polyvinyl pyrrolidone (PVP), starch, chitosan, poly acrylic acid (PAA), polyethyleneimine (PEI), carbohydrates, ethylene vinyl acetate (EVA) or a polyurethane.

In another aspect there is provided a process for metallization of a film of a material blend, the process comprising (i) vapor-depositing a metal on a surface of a film of the material blend, wherein the film is provided on a substrate (direct vapor deposition), or (ii) vapor-depositing a metal on a substrate to obtain a metalized surface on said substrate and transferring said metalized film onto a film of the material blend (indirect vapor deposition).

In some embodiments, the process comprises providing a film of the material blend on a substrate. The film of the material blend may be of various thicknesses. Typically, its thickness is between 0.5 and 20 μm. in some embodiments, the thickness is between 0.5 and 19 μm, 0.5 and 18 μm, 0.5 and 17 μm, 0.5 and 16 μm, 0.5 and 15 μm, 0.5 and 14 μm, 0.5 and 13 μm, 0.5 and 12 μm, 0.5 and 11 μm, 0.5 and 10 μm, 0.5 and 9 μm, 0.5 and 8 μm, 0.5 and 7 μm, 0.5 and 6 μm, 0.5 and 5 μm, 0.5 and 4 μm, 0.5 and 3 μm, 0.5 and 2 μm, 0.5 and 1 μm, 5 and 20 μm, 5 and 10 μm, 10 and 20 μm, 15 and 20 μm, 1 and 5 μm, 1 and 10 μm, 1 and 15 μm, or between 1 and 20 μm.

The metal film may have an averaged thickness between 500 Å (Angstrom) and 500 nm or 100 nm. The thickness may be between 500 Å and 100 nm, or between 500 521 and 95 nm, 500 Å and 90 nm, 500 Å and 85 nm, 500 Å and 80 nm, 500 Å and 75 nm, 500 521 and 70 nm, 500 Å and 65 nm, 500 Å and 60 nm, 500 Å and 55 nm, 500 Å and 50 nm, 500 Å and 45 nm, 500 Å and 40 nm, 500 Å and 35 nm, 500 Å and 30 nm, 500 Å and 25 nm, 500 Å and 20 nm, 500 Å and 15 nm, 500 Å and 10 nm, 500 Å and 5 nm, 500 Å and 4 nm, 500 Å and 3 nm, 500 Å and 2 nm, 500 Å and 1 nm, 1 and 100 nm, 5 and 100 nm, 10 and 100 nm, 20 and 100 nm, 30 and 100 nm, 40 and 100 nm, 50 and 100 nm, 60 and 100 nm, 70 and 100 nm, 80 and 100 nm or between 90 and 100 nm.

The process of vapor deposition of a metal, such as aluminum, on a film of the material blend surface or on a sacrificial surface, as disclosed herein, may comprise sputtering/evaporation of an aluminum metal under conditions suitable for achieving supersaturation of a vapor phase of and subsequent deposition of the metal onto the surface of the film or sacrificial substrate.

In some embodiments, the conditions suitable for achieving supersaturation of a vapor phase may comprise:
Metal, e.g., aluminum evaporation rate: between 3 and 15 g/min:
Winding speed: between 5 and 15 meters per second:
High vacuum: between 0.5 and 5×10⁻⁴ mbar: and
Cooling temperature: between −15 and −25° C.

The film of the material blend on top of which metallization is achieved is a film that comprises or consists a material blend, as defined herein.

The material blend used in products and processes of the invention is typically a blend of at least one cellulose material, which may be a cellulose nanomaterial or a cellulose micromaterial. Non-limiting examples include crystalline nanocellulose (CNC), nanofibrillar cellulose (NFC), microfibrillar cellulose (MFC), microcrystalline cellulose (MCC), cellulose nitrate, cellulose ester, cellulose acetate, ethyl cellulose, methyl cellulose, hydroxypropyl cellulose (HPC), hydroxyethyl cellulose (HEC), carboxymethyl cellulose (CMC), hydroxypropyl methylcellulose (HPMC), ethylhydroxyethyl cellulose (EHEC), methyl ethyl hydroxyethyl cellulose (MEHEC), or modified or oxidized forms thereof.

Alternatively, or additionally, the material blend may comprise at least one wax material. The at least one “wax” used may be any wax material known in the art. In most general terms, the wax may be a long chain ester or a long chain hydrocarbon.

In some embodiments, the at least one wax is a long chain ester that is a product of a long chain alcohol and a fatty acid. Typically, this wax is derived from an alcohol having at least 12 carbon atoms, and in some case having up to 40 carbon atoms.

In other embodiments, the at least one wax is a paraffin wax obtained by petroleum dewaxing processes. Unlike the ester waxes, the paraffin wax is a hydrocarbon or a mixture of hydrocarbons containing between 20 and 40 carbon atoms. In some embodiments, the paraffin wax is a branched hydrocarbon, or a mixture of hydrocarbons of different lengths, comprising at least one branched hydrocarbon. In some instances, the paraffin wax may also comprise a non-aliphatic material, such as an aromatic-based material.

Non-limiting examples of waxes include naturally derived waxes, synthetic waves, and semi-synthetic waxes. In some embodiments, the at least one wax is selected amongst sustainable waxes. The sustainable waxes are those which provide environmental, social and economic benefits and impose no environmental or public health risks. The sustainable waves may be selected from carnauba wax, vegetable wax, beeswax, soy wax, coconut wax, Candelilla wax and others.

In some embodiments, the at least one wax is carnauba wax or vegetable wax or beeswax or soy wax or coconut wax or Candelilla wax or any other wax known in the art.

In some embodiments, the at least one wax is a mixture of two or more waves, being optionally selected from waxes disclosed herein.

The at least one wax is a modified wax, based on a wax material, as defined herein, yet which is chemically modified to associate to at least one functional material. The “modified wax” is thus a conjugate of wax and a functional material. The modified wax is generally produced from the unmodified precursor or from other precursors to provide modified materials having more desirable properties than are known for the unmodified wax material. The modified properties may be modulated relative to the same properties in the unmodified wax, or new properties not existing in the unmodified wax or such properties that are eliminated or reduced relative to the unmodified wax. The modulation of the properties may result in enhancement or lessening of the properties.

The functional material conjugated to the wax to yield the modified form may be any such material capable of inducing modulation of properties. Such functional materials may be selected from hydrocarbons, polysaccharides, proteins, amino acids, aliphatic materials, lipids, acrylic polymers, thermoplastic polymers, polyolefin polymers such as PE, PP, and others. In some embodiments, the functional material is a polymer. Non-limiting examples include ethylene-vinyl acetate (EVA), polyethylene (PE), polypropylene (PP), polycarbonate (PC), polyethylene oxide (PEO), ethylene acrylic acid (EAA) and others.

In some embodiments, the functional material is cellulose or a cellulose-material (as defined herein, such as carboxyl methylcellulose (CMC), cellulose nanocrystal (CNC), microcrystalline cellulose (MCC) and others), starch, rosin, nylon and others.

The properties to be modified in the wax may be melting point, solubility, thermal stability, density, viscosity, thermal softening, and other mechanical or chemical properties. In some embodiments, the properties may be OTR and/or WVTR. In other words, in some embodiments, a modified wax is provided having improved OTR and/or WVTR properties.

In some embodiments, the modified wax is EVA-modified wax.

In some embodiments, the modified wax is an EVA-modified paraffin wax. EVA-modified paraffin is a material prepared by a chemical reaction between paraffin wax and EVA. The EVA grade and ratio of EVA to paraffin affects the resulted properties, such as softening temperature, mechanical properties, etc. Generally, the modified wax shows comparable range of softening and melting temperatures to paraffin wax (50-65° C.). The mechanical stability of the EVA modified wax is significantly higher than that of paraffin wax and is increased as EVA content goes higher. EVA modified wax also shows significantly higher adhesiveness capabilities than paraffin wax. EVA-modified waxes may be prepared according to procedures known in the art and as exemplified herein.

The latex used in products of the invention is typically derived from rubber trees as a milky liquid comprising 55% water and around 40% rubber material. Its chemical composition is a polymer of cis-1,4-polyisoprene having a molecular weight of 100,000 to 1,000,000 Da, with a small amount of material such as proteins, fatty acids, resins, and inorganic materials. The latex used in products of the invention is a non-coagulated form (e.g., not a coagulated rubber material, nor a vulcanized rubber). Alternatively, the latex may be synthetically prepared from petroleum-based chemicals.

As used herein, a cellulose material-based film is one which comprises in addition to the cellulose material one or more additives imparting together the superior OTR and/or WVTR properties. Similarly, the wax-based film comprises in addition to the wax material one or more additives imparting together the superior OTR and/or WVTR properties.

In some embodiments, the films consist a substrate, a metal film and a film of a blend of the cellulose material, the wax material and other additives.

The one or more additives used in a cellulose material-based and/or wax-based films may be selected as detailed herein. In some embodiments, the additive is polyvinyl alcohol (PVOH), polyvinyl acetate (PVAc), ethylene vinyl alcohol (EVOH), polyvinyl pyrrolidone (PVP), starch, chitosan, poly acrylic acid (PAA), polyethyleneimine (PEI), ethylene vinyl acetate (EVA), polyurethanes, hydroxypropyl methyl cellulose (HPMC), clay, lignin, latex, starch, an anti-foam material, alkenyl succinic anhydride (ASA), alkyl ketene dimer (AKD), nanoparticles (e.g., SiO₂, ZnO, and others), a protein, an amino acid, an aliphatic material, a lipid, an acrylic polymer, a thermoplastic polymer, a preservative, an epoxide, or a polyolefin.

Metalized products of the invention comprise or consist a cellulose material-based and/or wax-based film that is composed of or formed from a material blend comprising the cellulose material and/or the wax and optionally at least one additive. Non-limiting examples of such blends or blend formulations which make up films of the invention include (the number in parenthesis given ahead of the listed components designates the number of the formulation):
(1)—at least one cellulose-based material, as defined, and at least one additive selected from carbohydrates, crosslinking agents, polymers, natural additives, minerals, surfactants, nanoparticles and others:
(2)—at least one wax-based material, as defined, and at least one additive selected from carbohydrates, crosslinking agents, polymers, natural additives, minerals, surfactants, nanoparticles and others:
(3)—at least one cellulose-based material, as defined, at least one wax-based material, as defined herein, and at least one additive selected from carbohydrates, crosslinking agents, polymers, natural additives, minerals, surfactants, nanoparticles and others:
(4)—at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof, and at least one wax selected from naturally derived waxes, synthetic waxes, and semi-synthetic waxes, wherein the at least one wax may further be selected from carnauba wax, vegetable wax, beeswax, soy wax, coconut wax, Candelilla wax, and at least one modified wax, as defined, and at least one additive selected from carbohydrates, crosslinking agents, polymers, natural additives, minerals, surfactants, nanoparticles and others:
(5)—crystalline nanocellulose (CNC), and at least one wax selected from naturally derived waxes, synthetic waxes, and semi-synthetic waxes, wherein the at least one wax may be further selected from carnauba wax, vegetable wax, beeswax, soy wax, coconut wax, Candelilla wax, and at least one modified wax, as defined, and at least one additive selected from carbohydrates, crosslinking agents, polymers, natural additives, minerals, surfactants, nanoparticles and others:
(6)—nanofibrillar cellulose (NFC), and at least one wax selected from naturally derived waxes, synthetic waxes, and semi-synthetic waxes, wherein the at least one wax may be further selected from carnauba wax, vegetable wax, beeswax, soy wax, coconut wax, Candelilla wax, and at least one modified wax, as defined, and at least one additive selected from carbohydrates, crosslinking agents, polymers, natural additives, minerals, surfactants, nanoparticles and others:
(7)—microfibrillar cellulose (MFC), and at least one wax selected from naturally derived waxes, synthetic waxes, and semi-synthetic waxes, wherein the at least one wax may be further selected from carnauba wax, vegetable wax, beeswax, soy wax, coconut wax, Candelilla wax, and at least one modified wax, as defined, and at least one additive selected from carbohydrates, crosslinking agents, polymers, natural additives, minerals, surfactants, nanoparticles and others:
(8)—microcrystalline cellulose (MCC), and at least one wax selected from naturally derived waxes, synthetic waxes, and semi-synthetic waxes, wherein the at least one wax may be further selected from carnauba wax, vegetable wax, beeswax, soy wax, coconut wax, Candelilla wax, and at least one modified wax, as defined, and at least one additive selected from carbohydrates, crosslinking agents, polymers, natural additives, minerals, surfactants, nanoparticles and others:
(9)—CMC, and at least one wax selected from naturally derived waxes, synthetic waves, and semi-synthetic waves, wherein the at least one wax may be further selected from carnauba wax, vegetable wax, beeswax, soy wax, coconut wax, Candelilla wax, and at least one modified wax, as defined, and at least one additive selected from carbohydrates, crosslinking agents, polymers, natural additives, minerals, surfactants, nanoparticles and others:
(10)—HPMC, and at least one wax selected from naturally derived waxes, synthetic waves, and semi-synthetic waxes, wherein the at least one wax may be further selected from carnauba wax, vegetable wax, beeswax, soy wax, coconut wax, Candelilla wax, and at least one modified way, as defined, and at least one additive selected from carbohydrates, crosslinking agents, polymers, natural additives, minerals, surfactants, nanoparticles and others:
(11)—crystalline nanocellulose (CNC) and/or nanofibrillar cellulose (NFC) and/or microfibrillar cellulose (MFC) and/or microcrystalline cellulose (MCC), and/or CMC, and/or HPMC, and at least one wax selected from naturally derived waxes, synthetic waxes, and semi-synthetic waxes, wherein the at least one wax may be further selected from carnauba wax, vegetable wax, beeswax, soy wax, coconut wax, Candelilla wax, and at least one modified wax, as defined, and at least one additive selected from carbohydrates, crosslinking agents, polymers, natural additives, minerals, surfactants, nanoparticles and others:
(12)—at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof, carnauba wax, and at least one additive selected from carbohydrates, crosslinking agents, polymers, natural additives, minerals, surfactants, nanoparticles and others:
(13)—at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof, vegetable wax, and at least one additive selected from carbohydrates, crosslinking agents, polymers, natural additives, minerals, surfactants, nanoparticles and others:
(14)—at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof, beeswax, and at least one additive selected from carbohydrates, crosslinking agents, polymers, natural additives, minerals, surfactants, nanoparticles and others:
(15)—at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof, Candelilla wax, and at least one modified wax, as defined, and at least one additive selected from carbohydrates, crosslinking agents, polymers, natural additives, minerals, surfactants, nanoparticles and others:
(16)—at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof, at least one modified wax, and at least one additive selected from carbohydrates, crosslinking agents, polymers, natural additives, minerals, surfactants, nanoparticles and others:
(17)—crystalline nanocellulose (CNC), and/or CMC, and/or HPMC, and at least one additive selected from carbohydrates, crosslinking agents, polymers, natural additives, minerals, surfactants, nanoparticles and others:
(18)-crystalline nanocellulose (CNC), and/or CMC, and/or HPMC, and at least one additive selected from carbohydrates, crosslinking agents and polymers:
(19)—crystalline nanocellulose (CNC), and/or CMC, and/or HPMC, and/or MFC, and/or NFC, and at least one additive selected from carbohydrates, crosslinking agents, polymers, natural additives, minerals, surfactants, nanoparticles and others;
(20)—at least one wax or modified wax, and at least one additive selected from carbohydrates, crosslinking agents, polymers, natural additives, minerals, surfactants, nanoparticles and others;
(21)—at least one modified wax, and at least one additive selected from carbohydrates, crosslinking agents, polymers, natural additives, minerals, surfactants, nanoparticles and others:
(22)—at least two wax or modified wax materials, and at least one additive selected from carbohydrates, crosslinking agents, polymers, natural additives, minerals, surfactants, nanoparticles and others;
(23)—Starch, PVOH, CNC, HPMC and/or CMC:
(24)—Clay, PVOH, and CNC:
(25)—Starch, PVOH and CNC;
(26)—Starch, PVOH, CNC and Lignin:
(27)—Starch, PVOH, MFC and/or NFC, HPMC and/or CMC:
(28)—Wax and at least one surfactant:
(29)—Wax, latex and at least one surfactant:
(30)—Modified wax, latex and at least one surfactant:
(31)—Wax, modified wax, latex and at least one surfactant:
(32)—Wax, modified wax, an at least one surfactant:
(33)—Starch, PVOH, CNC, HPMC and/or CMC, modified wax and latex;
(34)—Starch (4.1-16.5 wt %), PVOH (5-15 wt %), CNC (0.1-5 wt %), HPMC and/or CMC (0.1-0.5 wt %):
(35)—Clay (4.2-13 wt %), PVOH (5-12 wt %), CNC (0.1-5 wt %);
(36)—Starch (5-14.5 wt %), PVOH (4.5-15.5 wt %), CNC (0.01-5 wt %);
(37)—Starch (4.5-15 wt %), PVOH (7-14.5 wt %), CNC (0.1-4 wt %), Lignin (7.3-13.1 wt %);
(38)—Starch (5.6-14.5 wt %), PVOH (6.5-14.2 wt %), MFC and/or NFC (0.1-5 wt %), HPMC and/or CMC (0.1-0.5 wt %);
(39)—Wax (2-30 wt %), surfactant (0.1-20 wt %);
(40)—Wax (2-22 wt %), Latex (2-30 wt %), surfactant (0.1-20 wt %);
(41)—Modified wax (e.g., EVA modified wax, 1-25 wt %), Latex (2-30 wt %), surfactant (0.1-20 wt %):
(42)—Wax (1.5-20 wt %), modified wax (e.g., EVA modified wax, 1-20 wt %), Latex (2-30 wt %), surfactant (0.1-20 wt %):
(43)—Wax (1.5-22 wt %), modified wax (e.g., EVA modified wax, 1-20 wt %), surfactant (0.1-20 wt %); and/or
(44)—Starch (1.5-9.5 wt %), PVOH (1.5-9.2 wt %), CNC (0.1-1.3 wt %), HPMC and/or CMC (0.1-1 wt %), modified wax (e.g., EVA modified wax) and Latex (combined in an amount of 4.5-30.3 wt %).

In each of the above blend formulas, the wt % values are calculated based on the formulation from which the films are eventually formed. Such formulations are aqueous based and comprise, in addition to the indicated materials and additives, water.

Films made up of blend formulations as above, comprise the materials as disclosed, wherein the relative amount of the materials in the dry film may differ (e.g., following evaporation of the medium, water). In some embodiments, the amounts of the materials in the dry films may be as follows:
(34)—Starch (20-80% dry), PVOH (20-80% dry), CNC (0.5-40% dry), HPMC and/or CMC (0.5-10% dry):
(35)—Clay (20-80% dry), PVOH (20-80% dry), CNC (0.5-40% dry);
(36)—Starch (20-80% dry), PVOH (20-80% dry), CNC (0.5-40% dry):
(37)—Starch (20-80% dry), PVOH (20-80% dry), CNC (0.5-40% dry), Lignin (30-70% dry):
(38)—Starch (20-80% dry), PVOH (20-80% dry), MFC and/or NFC (0.5-40% dry), HPMC and/or CMC (0.5-10% dry);
(44)—Starch (5-15% dry), PVOH (5-15% dry), CNC (2-8% dry), HPMC and/or CMC (0.5-2% dry), modified wax (e.g., EVA modified wax) and Latex (combined in an amount of 50-79% dry).

In some embodiments, the aforementioned blend formulations define film composition of any film defined herein as a “film of a material blend”. Additionally, the aforementioned blend formulations define the wet formulations (water based) form which the “film of a material blend” is formed. Thus, the aforementioned blend formulations may be regarded as wet (suspension) or dry (solid) formulations.

In some embodiments, each of film of a blend formulation comprising, consisting or formed of the formulations above may be provided on a substrate on in a product comprising a substrate or may be provided with a metalized film only.

The invention further provides a metalized film, the film being formed of a blend comprising:
(A) at least one cellulose material in an amount between 0.01 and 6 wt %, the at least one cellulose material is optionally selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof,
and/or
(B) at least one wax selected in an amount between 1 and 30 wt %, the at least one wax being optionally selected from naturally derived waxes, synthetic waxes, and semi-synthetic waxes, wherein the at least one wax may be selected from carnauba wax, vegetable wax, beeswax, soy wax, coconut wax, Candelilla wax, and at least one modified wax, as defined,
and
(C) at least one additive in an amount between 0.1 and 20 wt %, wherein the at least one additive is selected from carbohydrates, crosslinking agents, polymers, natural additives, minerals, surfactants, nanoparticles and others.

In some embodiments, the at least one additive is a carbohydrate.

In some embodiments, the at least one additive is a crosslinking agent.

In some embodiments, the at least one additive is a polymer.

In some embodiments, the at least one additive is latex.

In some embodiments, the at least one additive is PEI.

Where more than one member of each material group, e.g., at least two cellulose materials or at least two wax materials etc, is present in a blend of the invention, the indicated wt % amount is the amount of each member of the group or the combined wt % amount of all members in the same group. For example, where a blend formulation comprises two cellulose materials, e.g., CNC and HPMC, the amount or each of the CNC and the HPMC, independently, may be between 0.01 and 6 wt %. Alternatively, the amount of both the CNC and the HPMC, combined, may be between 0.01 and 6 wt %, provided that the amount of each of the CNC and the HPMC is between the indicated range amounts. The same principal applies to other combination of materials in blends for forming metalized films of the invention.

In some embodiments, the amount of the at least one cellulose material is between 0.01 and 6 wt %, between 0.05 and 6 wt %, between 0.1 and 6 wt %, between 0.1 and 5 wt %, between 0.1 and 4 wt %, between 0. 1 and 3 wt %, between 0.1 and 2 wt %, between 0.1 and 1 wt %, or between 0.1 and 0.5 wt %, wherein each of the amount range constitutes an independent embodiment and wherein each amount range constitutes an independent amount for each of the cellulose materials disclosed herein, independently.

In some embodiments, the amount of the at least one wax is between 1 and 30 wt %, between 1.5 and 30 wt %, between 2 and 30 wt %, between 2.5 and 30 wt %, between 3 and 30 wt %, between 3.5 and 30 wt %, between 4 and 30 wt %, between 4.5 and 30 wt %, between 5 and 30 wt %, between 1 and 28 wt %, between 1 and 26 wt %, between 1 and 25 wt %, between 1 and 22 wt %, between 1 and 20 wt %, between 1 and 15 wt %, between 1 and 10 wt %, between 5 and 25 wt %, between 5 and 20 wt %, or between 5 and 10 wt %, wherein each of the amount range constitutes an independent embodiment and wherein each amount range constitutes an independent amount for each of the wax materials disclosed herein, independently.

In some embodiments, the amount of the at least one additive between 0.1 and 20 wt %, between 0.5 and 20 wt %, between 1 and 20 wt %, between 2 and 20 wt %, between 3 and 20 wt %, between 4 and 20 wt %, between 5 and 20 wt %, between 6 and 20 wt %, between 7 and 20 wt %, between 8 and 20 wt %, between 9 and 20 wt %, between 10 and 20 wt %, between 0.1 and 18 wt %, between 0.1 and 16 wt %, between 0.1 and 15 wt %, between 0.1 and 13 wt %, between 0.1 and 12 wt %, between 0.1 and 10 wt %, between 0.1 and 9 wt %, between 0.1 and 8 wt %, between 0.1 and 6 wt %, between 0.1 and 4 wt %, between 0.1 and 2 wt %, between 0.1 and 1 wt %, between 4 and 15 wt %, between 5 and 15 wt %, between 1 and 9 wt %, between 0.1 and 10 wt %, between 4 and 16 wt %, between 5 and 12 wt %, between 4 and 13 wt %, between 7 and 13 wt %, or between 7 and 14 wt %, wherein each of the amount range constitutes an independent embodiment and wherein each amount range constitutes an independent amount for each of the additive materials disclosed herein, independently.

Thus, in some embodiments, metalized products according to the invention comprise or consist a film of a material blend and a metal film, and optionally a substrate, wherein the metallization of the film of the material blend is optionally achieved by vapor deposition, wherein the film of the material blend comprises any of the formulation blends disclosed hereinabove. In some embodiments, the material blend is
Starch, PVOH, CNC, HPMC and/or CMC: as defined, or
Clay, PVOH, and CNC: as defined, or
Starch, PVOH and CNC: as defined, or
Starch, PVOH, CNC and Lignin: as defined, or
Starch, PVOH, MFC and/or NFC, HPMC and/or CMC: as defined, or
Wax and at least one surfactant: as defined, or
Wax, latex and at least one surfactant: as defined, or
Modified wax, latex and at least one surfactant: as defined, or
Wax, modified wax, latex and at least one surfactant: as defined, or
Wax, modified wax, an at least one surfactant: as defined, or
Starch, PVOH, CNC, HPMC and/or CMC, modified wax and latex.

In some embodiments, metalized films according to the invention are configured as OTR and/or WVTR superior films. OTR as well as WVTR values have been achieved by carefully tailoring the composition of the blend film, e.g., the components used, the relative amounts thereof etc, as well as the metal use for forming the metal film thereon. Superior results have been achieved when any of the following metals was used: zinc, aluminum, iron, titanium and tin. Each of the indicated metals was used with blend formulations, as disclosed herein, to form metalized products. In some embodiments, the metal is zinc, or aluminum, or iron, or titanium, or tin and the blend formulation is any of blend formulations (1) through (44) detailed herein.

In some embodiments, the metalized film is formed of a metal selected from zinc, aluminum, iron, titanium and tin, constituting a metal film, and the blend composition constituting the blend-based film, the formulation comprising:
(A) at least one cellulose material in an amount between 0.01 and 6 wt %, the at least one cellulose material is optionally selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof,
and/or
(B) at least one wax selected in an amount between 1 and 30 wt %, the at least one wax being optionally selected from naturally derived waxes, synthetic waxes, and semi-synthetic waxes, wherein the at least one wax may be selected from carnauba wax, vegetable wax, beeswax, soy wax, coconut wax, Candelilla wax, and at least one modified wax, as defined,
and
(C) at least one additive in an amount between 0.1 and 20 wt %, wherein the at least one additive is selected from carbohydrates, crosslinking agents, polymers, natural additives, minerals, surfactants, nanoparticles and others.

In some embodiments, the metalized product comprising a metal film, e.g., vapor deposited, on a film formed of a blend material, wherein the metalized film or product exhibiting superior OTR properties. In some embodiments, the metal is aluminum and the blend material is selected from:
(17)—crystalline nanocellulose (CNC), and/or CMC, and/or HPMC, and at least one additive selected from carbohydrates, crosslinking agents, polymers, natural additives, minerals, surfactants, nanoparticles and others:
(18)—crystalline nanocellulose (CNC), and/or CMC, and/or HPMC, and at least one additive selected from carbohydrates, crosslinking agents and polymers:
(19)—crystalline nanocellulose (CNC), and/or CMC, and/or HPMC, and/or MFC, and/or NFC, and at least one additive selected from carbohydrates, crosslinking agents, polymers, natural additives, minerals, surfactants, nanoparticles and others:
(23)—Starch, PVOH, CNC, HPMC and/or CMC:
(24)—Clay, PVOH, and CNC;
(25)—Starch, PVOH and CNC:
(26)—Starch, PVOH, CNC and Lignin;
(27)—Starch, PVOH, MFC and/or NFC, HPMC and/or CMC:
(33)—Starch, PVOH, CNC, HPMC and/or CMC, modified wax and latex:
(34)—Starch (4.1-16.5 wt %), PVOH (5-15 wt %), CNC (0.1-5 wt %), HPMC and/or CMC (0.1-0.5 wt %):
(35)—Clay (4.2-13 wt %), PVOH (5-12 wt %), CNC (0.1-5 wt %):
(36)—Starch (5-14.5 wt %), PVOH (4.5-15.5 wt %), CNC (0.01-5 wt %):
(37)—Starch (4.5-15 wt %), PVOH (7-14.5 wt %), CNC (0.1-4 wt %), Lignin (7.3-13.1 wt %);
(38)—Starch (5.6-14.5 wt %), PVOH (6.5-14.2 wt %), MFC and/or NFC (0.1-5 wt %), HPMC and/or CMC (0.1-0.5 wt %);
(44)—Starch (1.5-9.5 wt %), PVOH (1.5-9.2 wt %), CNC (0.1-1.3 wt %), HPMC and/or CMC (0.1-1 wt %), modified wax (e.g., EVA modified wax) and Latex (combined in an amount of 4.5-30.3 wt %);
Or
(34)—Starch (20-80% dry), PVOH (20-80% dry), CNC (0.5-40% dry), HPMC and/or CMC (0.5-10% dry);
(35)—Clay (20-80% dry), PVOH (20-80% dry), CNC (0.5-40% dry);
(36)—Starch (20-80% dry), PVOH (20-80% dry), CNC (0.5-40% dry):
(37)—Starch (20-80% dry), PVOH (20-80% dry), CNC (0.5-40% dry), Lignin (30-70% dry):
(38)—Starch (20-80% dry), PVOH (20-80% dry), MFC and/or NFC (0.5-40% dry), HPMC and/or CMC (0.5-10% dry):
(44)—Starch (5-15% dry), PVOH (5-15% dry), CNC (2-8% dry), HPMC and/or CMC (0.5-2% dry), modified wax (e.g., EVA modified wax) and Latex (combined in an amount of 50-79% dry).

In some embodiments, the metalized product comprises a metal film, e.g., vapor deposited, on a film formed of a blend material, wherein the metalized product exhibits superior WVTR properties. In some embodiments, the metal is aluminum and the blend material is selected from:
(20)—at least one wax or modified wax, and at least one additive selected from carbohydrates, crosslinking agents, polymers, natural additives, minerals, surfactants, nanoparticles and others:
(21)—at least one modified wax, and at least one additive selected from carbohydrates, crosslinking agents, polymers, natural additives, minerals, surfactants, nanoparticles and others:
(22)—at least two wax or modified wax materials, and at least one additive selected from carbohydrates, crosslinking agents, polymers, natural additives, minerals, surfactants, nanoparticles and others:
(28)—Wax and at least one surfactant:
(29)—Wax, latex and at least one surfactant;
(30)—Modified wax, latex and at least one surfactant:
(31)—Wax, modified wax, latex and at least one surfactant:
(32)—Wax, modified wax, an at least one surfactant:
(39)—Wax (2-30 wt %), surfactant (0.1-20 wt %):
(40)—Wax (2-22 wt %), Latex (2-30 wt %), surfactant (0.1-20 wt %);
(41)—Modified wax (e.g., EVA modified wax, 1-25 wt %), Latex (2-30 wt %), surfactant (0.1-20 wt %):
(42)—Wax (1.5-20 wt %), modified wax (e.g., EVA modified wax, 1-20 wt %), Latex (2-30 wt %), surfactant (0.1-20 wt %); (43)—Wax (1.5-22 wt %), modified wax (e.g., EVA modified wax, 1-20 wt %), surfactant (0.1-20 wt %); and/or
(44)—Starch (1.5-9.5 wt %), PVOH (1.5-9.2 wt %), CNC (0.1-1.3 wt %), HPMC and/or CMC (0.1-1 wt %), modified wax (e.g., EVA modified wax) and Latex (combined in an amount of 4.5-30.3 wt %);
Or
(39)—Wax (70-99% dry), surfactant (1-30% dry);
(40)—Wax (30-69% dry), Latex (30-69% dry), surfactant (1-40% dry);
(41)—Modified wax (e.g., EVA modified wax, 30-69% dry), Latex (30-69% dry), surfactant (1-40% dry):
(42)—Wax (15-54% dry), modified wax (e.g., EVA modified wax, 15-54% dry), Latex (30-69% dry), surfactant (1-40% dry):
(43)—Wax (30-69% dry), modified wax (e.g., EVA modified wax, 30-69% dry), surfactant (1-40% dry); and/or
(44)—Starch (5-15% dry), PVOH (5-15% dry), CNC (2-8% dry), HPMC and/or CMC (0.5-2% dry), modified wax (e.g., EVA modified wax) and Latex (combined in an amount of 450-79% dry).

In some embodiments, the metalized film or product comprising a metal film, e.g., vapor deposited, on a film formed of a blend material, wherein the metalized product exhibiting superior OTR and WVTR properties. In some embodiments, the metal is aluminum and the blend material comprises starch, PVOH, CNC, HPMC and/or CMC, modified wax and latex. In some embodiments, the blend material comprises starch (1.5-9.5 wt %), PVOH (1.5-9.2 wt %), CNC (0.1-1.3 wt %), HPMC and/or CMC (0.1-1 wt %), modified wax (e.g., EVA modified wax) and Latex (combined in an amount of 4.5-30.3 wt %).

In some embodiments, blends formulations from which films are made are aqueous formulations (containing water) have a viscosity below 3500 cP. In some embodiments, the viscosity is between 100 and 3500 cP or between 100 and 1000 cP or below: 1000 cP or below 500 cP or below 150 cP.

While films of the blend materials may comprise at least one cellulose material or wax and at least one additive as defined, the additives do not form separate films in products of the invention. In other words, metalized products of the invention do not comprise or exclude films consisting of polyvinyl alcohol (PVOH), or polyvinyl acetate (PVAc), or ethylene vinyl alcohol (EVOH), or polyvinyl pyrrolidone (PVP), or starch, or chitosan, or poly acrylic acid (PAA), or polyethyleneimine (PEI), or carbohydrates, or ethylene vinyl acetate (EVA), or polyurethanes, or hydroxypropyl methyl cellulose (HPMC), or clay, or lignin, or latex, or epoxides, alkenyl succinic anhydride (ASA), Alkyl ketene dimer (AKD).

Material blends used according to the present invention are water-based and may comprise surfactants (such as fatty acids, Span, Tween, sucrose ester-based surfactants, SDS, and others), salts (organic or inorganic), adhesives, emulsifiers, stabilizers, pH stabilizers, colorants and other materials, as detailed herein.

The concentration of a blend in an aqueous formulation may be between 5 and 70 w1%.

Excluded from additives that may be used are formaldehydes and any other component that are not approved for food-contact, or which are not environmentally friendly or which are generally toxic.

In some embodiments, the cellulose material used in products of the invention is a cellulose nanomaterial, being in some embodiments CNC.

As known in the art, CNC, also known as nanocrystalline cellulose (NCC) or cellulose whiskers are fibers produced from cellulose, wherein the CNC are typically high-purity single crystals. They constitute a generic class of materials having mechanical strengths equivalent to the binding forces of adjacent atoms. The resultant highly ordered structure produces not only unusually high strengths but also significant changes in thermal, electrical, optical, magnetic, ferromagnetic, dielectric, conductive, and even superconductive properties. The tensile strength properties of CNC are far above those of the current high volume content reinforcements and allow the processing of the highest attainable composite strengths. The CNC may be prepared by any one method known in the art. For example, the CNC may be prepared by methods disclosed in U.S. Pat. No. 9,464,142, herein incorporated by reference.

In some embodiments, the CNC is characterized by having at least 50 percent crystallinity. In some embodiments, the CNC is monocrystalline. In some embodiments, the CNC is high purity monocrystalline material.

In some embodiments, the nanocrystals of the CNC have a length of at least about 50 nm. In other embodiments, they are at least about 100 nm in length or are at most 1,000 nm in length. In other embodiments, the nanocrystals are between about 100 nm and 1,000 nm in length, 100 nm and 900 nm in length, 100 nm and 600 nm in length, or between 100 nm and 500 nm in length.

In some embodiments, the nanocrystals are between about 10 nm and 100 nm in length, 100 nm and 1,000 nm, 100 nm and 900 nm, 100 nm and 800 nm, 100 nm and 600 nm, 100 nm and 500 nm, 100 nm and 400 nm, 100 nm and 300 nm, or between about 100 nm and 200 nm in length.

The nanocrystals may be selected to have an averaged aspect ratio (length-to-diameter ratio) of 10 or more. In some embodiments, the averaged aspect ratio is between 10 and 100, or between 20 and 100, or between 30 and 100, or between 40 and 100, or between 50 and 100, or between 60 and 100, or between 70 and 100, or between 80 and 100, or between 90 and 100, or between 61 and 100, or between 62 and 100, or between 63 and 100, or between 64 and 100, or between 65 and 100, or between 66 and 100, or between 67 and 100, or between 68 and 100, or between 69 and 100.

In some embodiments, the averaged aspect ratio is between 67 and 100.

The film of the material blend may be formed on a solid substrate which may be sacrificial, namely a substrate which may be peeled off or decomposed or optionally replaced. Typically, the substrate is a solid substrate on which the film is formed to fabricate a metalized film of a direct configuration, as disclosed herein. In some embodiments, the substrate may be used for forming the film of the material blend and thereafter peeled off to afford a self-standing material blend film. Such a self-standing film may be used for fabricating a metalized film of an inverse configuration, as disclosed herein.

The substrate may be of a material selected from a polymeric material, a paper or paper-based material, a polymer coated paper-based material, a fabric material, a porous material and a membrane material. In some embodiments, the substrate is paper or a paper-based material such as a paperboard.

In some embodiments, the substrate is selected from a polymeric material, a paper or paper-based material, a polymer coated paper-based material, e.g., a paperboard, a nanocellulose film, nanocellulose/polymer film, a fabric material, a porous material and a membrane material.

The “polymeric material”, when used as an independent layer or as a coating layer of a paper-based material or a nanocellulose material or as an additive to any of the materials constructing any of the layers, may be a material belonging to any known polymeric material or resin, such as thermoplastic polymers and thermoset polymers. The polymer may be selected amongst such polymers as polyethylene, polypropylene, polyvinyl alcohol, ethylene vinyl alcohol, polyamide, polystyrene, polylactic acid, polyhydroxyalkanote, polycaprolactone, polyhydroxybutyrate, polyvinyl acetate, polyacrylonitrile, polybutylene succinate, polyvinylidene chloride, starch, cellulose, polyhydroxyvalerate, polyhydroxy hexanoate, polyanhydrides, polyethylene terephthalate, polyvinyl chloride and polycarbonate. In some embodiments, the polymeric material is polyester (which may be selected amongst thermoset and thermoplastics).

In some embodiments, the polymer is selected from polyethylene, polypropylene, polyester, polyvinyl alcohol, ethylene vinyl alcohol, polyamide, polystyrene, polylactic acid, polyhydroxyalkanote, polycaprolactone, polyhydroxy butyrate, polyvinyl acetate, polyacrylonitrile, polybutylene succinate, polyvinylidene chloride, starch, cellulose, polyhydroxyvalerate, poly hydroxy hexanoate, poly anhydrides., polyethylene terephthalate, polyvinyl chloride and polycarbonate, or any blend of two or more thereof.

As used herein, “paper or paper-based material” is a material as known in the art. The paper or paper-based material may be used as such or may be used coated with a polymer on one or both its faces. In some embodiments, this paper-coated material is a paperboard. In some embodiments, the paper is Kraft paper. As known in the art, Kraft paper is a paper or paperboard (cardboard) produced from chemical pulp produced in the Kraft process, as known in the art. The paper is a porous paper with high elasticity and high tear resistance, designed for packaging products with high demands for strength and durability. Thus, the paper may additionally be selected from paper-based packaging materials.

In some embodiments, the paper is selected from bank paper, banana paper, bond paper, book paper, coated paper products, construction paper, sugar paper, cotton paper, fish paper, inkjet paper, Kraft paper, Glassine paper, Sack Kraft paper, laid paper, leather paper, mummy paper, oak tag paper, sandpaper, Tyvek paper, wallpaper, Washi paper, waterproof paper, wax paper, wove paper, Xuan paper and others.

As known in the art, commercial papers or paper-based products of any kind described above, may contain additives such as clays, calcium carbonate, latex, lignin, starch, titanium oxide, etc., which are added to the paper in its production process.

The “fabric material” is any such material known in the art that is typically a flexible material constructed of a network of natural or artificial fiber materials. The fabric may be any textile, natural fabric, synthetic fabric, knit, woven material, nonwoven material or mesh of a material selected from cellulose, viscose, glass fibers, carbon fibers and synthetic fibers. In some embodiments, the fabric may be in the form of a porous material or a membrane, selected as indicated.

The “porous material” or “membrane material” is generally a material containing pores that can hold or contain solid, liquid or gaseous materials. In some embodiments, the pores are voids, namely empty of any such material. In some embodiments, the porous material acts as a membrane, namely as a selective barrier with a degree of selectivity being dependent on the membrane pore size. In some embodiments, the membrane may be fabric based or paper based.

The metalized films of the invention may be used for fabricating barrier material such as packaging materials. The packaging may be for holding liquids or solids.

The films may be formed into a sheet or a folded or shaped sheet of any size and shape. It may be printed or colored, may be fully transparent or opaque and may or may not be surface treated. The sheet may be cut, folded, or processed into any one shape, size or object such as a pocket or an enclosure or an envelope or a container that is formed of the sheet. In some embodiments, the object is for packaging of goods, foods, liquids, pharmaceuticals or any material requiring isolation or protection from the environment. e.g., gases, water vapor, light exposure and from other damaging agents or conditions which the composite material can protect from (e.g., by forming an impermeable barrier).

As known in the art, packaging materials demonstrating excellent gas barrier properties such as those of the present invention are suitable for long-term, aseptic packaging of foods and beverages, whether in liquid or solid forms. Typically, excellent oxygen barrier will exhibit OTR values of below: 10 ml/m²day. Good oxygen barrier will show OTR values of few dozens, and so on. The OTR values measured for metalized films according to the invention are below 1 ml/m²day: thus, providing uniquely low barrier properties.

As the artisan will realize, typically, OTR measurements are carried out at a relative humidity of 0% or 50%. Fabricating a product having a low OTR at a relative humidity of 70% is clearly uncommon and unique. When measured at a relative humidity of 70%, metalized films of the invention exhibit OTR values around or below 1 ml/m²day. Such films are new in the field. Accordingly, the invention also provides a metalized film having an OTR below 1 ml/m²day, as measured at 70% relative humidity, at 23° C.

Also provided is a metalized film having a WVTR of between 2 and 10 gr/m²·day, as measured at 90% relative humidity, at 38° C.

Further provided is a packaging material in a form of a metalized film according to the invention, and methods of using metalized films according to the invention for fabricating packaging materials for liquids and solids.

The metalized films of the invention may be regarded as composite materials, as a distinction between the metallized film and the film of the material blend cannot at times be made. The invention thus also provides a composite material in the form of a material continuum (being substantially free of distinct material regions) comprising (intimately associated) a material blend, as defied, and at least one metal, wherein the at least one metal forming a nonpeelable interaction with the material blend, wherein optionally the at least one metal partially interpenetrates (or impregnates) the material blend (and/or vice versa) and wherein the composite material is provided on (or associated or bonded to) a surface region of a substrate.

Further provided is a hybrid material (a composite), the material comprising a first region of at least one metal and a second region of a material blend, the first and second regions forming a material continuum of materials differing in composition, wherein an interface between the first and second regions being graded with at least an amount of said at least one metal and said material blend, and wherein the hybrid material is provided on (or associated or bonded to) a surface region of a substrate.

As stated herein, the “composite material” is a hybrid material of the metal and the material blend, forming together a graded material continuum characterized by regions of different compositions. These regions are not distinct: namely the boundary between the metal region and the material blend is not distinct. In other words, the two regions cannot be peeled off one from another without causing damage to the composite as a whole or to the material component from which peeling is attempted.

The regions of different compositions defining the graded material continuum are at least a metal region, a region of a material blend and a graded region provided between the two material regions. The graded region comprises an amount of the metal and an amount of the material blend. This graded region is typically amorphic in structure, yet smaller in thickness relative to the metal and blend regions. The grading of one material into the other may be regarded as mechanical adhesion that intimately associates or fuses the two material regions into a nonpeelable interaction. This mechanical adhesion, being typically physical in nature (i.e., substantially not involving the formation of chemical bonds between the metal and the blend material), which does not involve the use of adhesive materials, results from interpenetration of the metal into the blend material region, typically into nano or micro-sized pores present in the blend material, thereby forming the graded region. This interpenetration or impregnation of the metal into the blend material and/or the blend material into the metal may be achieved by proper processing conditions.

The interpenetration or impregnation does not involve use of adhesive materials.

The degree of interpenetration of one material into the other may vary based, inter alia, the material used, the composition of the material, the manufacturing conditions, and others. In some embodiments, the impregnation is substantially along the full association region between the two materials. In other embodiments, impregnation is in some regions along the association region of the two materials.

The amount of each of the materials in the graded region decreases away from the center of each of the two material regions. In other words, for example, the amount of metal in the graded region decreases with a decrease in the distance to the material blend region.

The composite, being comprised of at least a metal and a blend material, may be provided with one or more additional materials. In such multi-material composite, the additional material may be present with the metal-in the metal region, with the blend materail-in the blend material region, in the graded region (exclusively or additionally) or associated with either or both metal and/or material blend regions. In some composites, the metal/blend composite, as defined, is further provided with an additional material that is associated with an exposed surface region of the metal region and/or the blend region. For example, a composite is provided wherein the metal region is associated with the material blend on one end and with a further material on the other end. Alternatively, or additionally, the material blend is provided with a metal region at one end and with a different material at its other end.

In some embodiments, the composite comprises a third material region that separates between the metal region and the material blend region. In such implementations of the technology, the material of the third material region may interpenetrate the material blend region, on one end, and be impregnated with a metal region, on the other.

Products of the invention may be formed into any shape and form. As a packaging material, the composite may be formed into sheets or three-dimensional articles. To endow the composite with mechanical stability or in order to shape the composite into a desired form, the composite may be provided on a surface or a surface region of a substrate. The substrate may be any solid material, such as and not limited to metal substrates, glass substrates, polymeric substrates, biopolymeric materials, paper substrates, wood substrates, silicon substrates, heat sensitive substrates, substantially two-dimensional substrates, three-dimensional substrates and others.

In some embodiments, the substrate is a paper material, a polymer or a biopolymer.

In some embodiments, the substrate is a polymer selected amongst polyethylene, polypropylene, polyester, polyvinyl alcohol, ethylene vinyl alcohol, polyamide, polystyrene, polylactic acid, polyhydroxyalkanote, poly caprolactone, polyhydroxy butyrate, polyvinyl acetate, polyacrylonitrile, polyvinylidene chloride, cellulose, polyethylene terephthalate, polyvinyl chloride and polycarbonate.

In some embodiments, the substrate is a paperboard, optionally coated with a polymer selected from polyethylene, polypropylene, polyester, polyvinyl alcohol, ethylene vinyl alcohol, polyamide, polystyrene, polylactic acid, polyhydroxyalkanote, polycaprolactone, polyhydroxy butyrate, polyvinyl acetate, polyacry lonitrile, polyvinylidene chloride, cellulose, polyethylene terephthalate, polyvinyl chloride and polycarbonate.

In some embodiments, the product is formed into an article of manufacture comprising a metal at least partially impregnating CNC, the metal being nonpeelable from said CNC, wherein the metal and the CNC being formed (or being associated or being bonded to) on a surface region of a substrate.

The invention further provides a film of a product of the invention coating a surface of a substrate material. In some embodiments, the substrate forms part of the composite, wherein the substrate material is in association with either the metal region or the material blend region. In either case, the metal or material blend impregnates or interpenetrates the substrate material, thereby forming a composite material with the substrate. Such interpenetration or impregnation does not allow peeling off the metal/blend composite from the substrate. Thus, the invention further provides a metamaterial composite, wherein each of the composite materials interpenetrates or impregnates at least one other material of the composite, thus providing a material continuum, as described herein.

In some embodiments, the substrate is associated with the CNC region and the CNC interpenetrates or impregnates the substrate material.

In some embodiments, the substrate is a polymer sheet or a sheet of a paper material, e.g., a cardboard, impregnated with either a metal or a material blend. In such an implementation, the substrate, e.g., cardboard, is treated with a material blend that interpenetrates the cardboard sheet and associates therewith. This composite is thereafter treated with a metal to form a substrate/blend/metal composite. This exemplary composite may be alternatively prepared by forming the composite on a surface of a metal sheet or foil.

### DETAILED DESCRIPTION OF EMBODIMENTS

A process as disclosed herein was employed on a variety of blend formulations and metal compositions to afford metalized films of a variety of compositions. The conditions provided herein are exemplary and may be varied based on the formulation, the metal, the substrate, etc.

### Blend Formulations

The following exemplary blend formulations were used to form blend films on a substrate such as a paper substrate, a polymer substrate or a biopolymer substrate:

### Formulation 1:

Starch (4.1-16.5 wt %), PVOH (5-15 wt %), CNC (0.1-5 wt %), HPMC and/or CMC (0.1-0.5 wt %);

### Formulation 2

Kaolin (as clay, 4.2-13 wt %), PVOH (5-12 wt %), CNC (0.1-5 wt %);

### Formulation 3

Starch (5-14.5 wt %), PVOH (4.5-15.5 wt %), CNC (0.01-5 wt %);

### Formulation 4:

Starch (4.5-15 wt %), PVOH (7-14.5 wt %), CNC (0.1-4 wt %), Lignin (7.3-13.1 wt %);

### Formulation 5

Starch (5.6-14.5 wt %), PVOH (6.5-14.2 wt %), MFC and/or NFC (0.1-5 wt %), HPMC and/or CMC (0.1-0.5 wt %);

### Formulation 6

Soy wax (2-30 wt %), tween 20 (0.1-20 wt %);

### Formulation 7

Paraffin (2-22 wt %), Latex (2-30 wt %), span 80 (0.1-20 wt %);

### Formulation 8

EVA modified wax (1-25 wt %), Latex (2-30 wt %), tween 20 (0.1-20 wt %);

### Formulation 9

Carnauba wax (1.5-20 wt %), EVA modified wax (1-20 wt %), Latex (2-30 wt %), SDS (0.1-20 wt %);

### Formulation 10

Candalilla wax (1.5-22 wt %), EVA modified wax (1-20 wt %), tween 80 (0.1-20 wt %);

### Formulation 11

Starch (1.5-9.5 wt %), PVOH (1.5-9.2 wt %), CNC (0.1-1.3 wt %), HPMC and/or CMC (0.1-1 wt %), EVA modified wax and Latex (combined in an amount of 4.5-30.3 wt %).

### The Metallizer Unit and Metallization Conditions

The metallizer used for achieving metalizing a film of a material blend or a sacrificial surface was a single to multi-chamber metallizer. The film to be metallized was driven under reduced pressure conditions to a chamber comprising the metal vapor sources, for example boats heated by the Joule effect and fed by a metal wire, such as an aluminum wire, or any other type of suitable source.

Sublimation of the metal, e.g., aluminum and condensation of the metal on the surface to be metallized was completed using the following conditions:
Metal, e.g., aluminum evaporation rate: between 3 and 15 g/min;
Winding speed: between 5 and 15 meters per second:
High vacuum: between 0.5 and 5×10⁻⁴ mbar; and
Cooling temperature: between-15 and-25° C.

Other suitable conditions have been employed, depending on the metal used, the film or surface on which deposition is to be achieved etc.

A metalized film structured as below was formed:
A. Paper/Plastic/Biopolymer-thickness of 10-400 μm.
B. blend formula-thickness of 0.5-20 μm.
C. Metallization layer-thickness of 0.1-100 nm.

### Metal Deposition

Transfer or indirect vapor deposition—High vacuum metallization of a plastic for transferal to the material blend film—
A. Reel of plastic was metalized using a high vacuum process.
B. The metalized plastic was attached to the paper via adhesive.
C. The product was allowed to harden.
D. The plastic and paper were separated leaving a layer of metal attached to the material blend only.

Direct vapor deposition—metallization was performed directly on the material blend film—
A. The substrate was coated before metallization with a material blend to afford a film thereof.
B. The material blend film was metallized via vacuum metallization: the aluminum vapor adhered to the surface of the material blend, producing a metal coating.

### Comparative Data

Blend compositions not including one or more of the components constituting formulations of the invention, or comprising weight amounts that are outside the indicated amounts herein, were tested. Similar formulations used include:

### Comparative Formulation 1

Starch (13%), PVOH (7%), CNC (1.5%) and CMC (1%), provided a suspension with a viscosity higher than about 4000 cP, which did not allow for applicability in regular coating machines. Films formed of this formulation demonstrated OTR performance that was inferior by 10 folds, compared to a blend of the invention having a viscosity below 1000 cP, and a highly applicable OTR value of below 2.

The inability to be properly applied also resulted in insufficient blocking of paper pores and insufficient smoothening of the surface (10% reduction in roughness, compared to 25% reduction in roughness for a blend formulation of the invention), leading to reduced performance after metallization, compared to paper substrates coated with a metalized blend (formulation 34).

### Comparative Formulation 2

Wax (30%), latex (5%) and surfactant (8%), provided a suspension that was not stable and suffered from phase separation. The suspension was not homogeneous and when applied, aggregates were formed and the barrier performance was poor (WVTR>50). Metallization on such film was not effective and did not lead to improved performances. A blend of the invention (formulation 40), in contrast, led to stable and homogenous suspensions, smooth and homogeneous films and excellent barrier performances (WVTR =8), that are further improved by metallization (WVTR=3).

### Conclusions and Analysis

For evaluating OTR and/or WVTR properties of structures of the invention compared with metalized only surfaces and other similar structures, comparative structures were manufactured and tested.
1. Comparison between structures formed of a metalized film or a blend material derived from formulations used as above to a structure comprising a metalized substrate without a film of a blend material yielded the following conclusions:
   A. Vapor metallization was not possible on porous substrates such as paper. This results in a structure demonstrating no barrier properties.
   B. High surface roughness reduced effectivity of the metallization layer and led to poor performance. A layer of a material blend reduced surface roughness, leading to an improved metallization and barrier performance.

Comparison of OTR (at 70% RH, 23° C.) and WVTR water (at 90% RT, 38° C.) performance is depicted in the Table 1 below.

TABLE 1
OTR and WVTR Properties of products according to embodiments
of the invention versus other products-- Comparative Data.
The blend films comprised different formulations of the invention.
Data obtained for formulations 34, 36 and 44 which provided
substantially same results is provided in the Table.

| | OTR | WVTR |
|---|---|---|
| Structure | (ml/m² · day) | (gr/m² · day) |
| Glassine paper | >200 | >200 |
| Glassine paper/metallization | >200 | 8 |
| Glassine paper/blend/metallization | 0.8 | 2.5 |
| PP/Glassine paper/metallization/PP | 4.2 | 1.8 |
| PP/Glassine paper/blend/metallization/PP | 0.06 | 1.6 |
| Specialization paper | 6 | >200 |
| Specialization paper/metallization | 6 | 19 |
| Specialization paper/blend/metallization | 0.5 | 7 |
| PP/Specialization paper/metallization/PP | 0.6 | 1.7 |
| PP/Specialization paper/ | 0.06 | 1.6 |
| blend/metallization/PP | | |
| C1S (coated one side) paper | >200 | >200 |
| C1S (coated one side)/metallization | >200 | >200 |
| C1S (coated one side)/blend/metallization | 0.7 | 4.8 |

As demonstrated in Table 1, metallization on bare paper such as a glassine paper, CIS paper and even on specialized paper did not improve oxygen barrier performance of the paper. The OTR measured for the bare papers was greater than 200 ml/m²·day in the case of the glassine and CIS papers, and 6 ml/m²·day for the specialized paper. The WVTR for the bare papers was similarly not impressive.

However, when metallization was achieved on a material blend film, the oxygen and water vapor barrier performances were improved by at least one order of magnitude. An OTR below 1 ml/m²·day was measured at 70% relative humidity, at 23° C. The WVTR was similarly superior, exhibiting values around or below 5 gr/m²·day.

Furthermore, lamination with a polypropylene layer (PP) demonstrated even better and improved OTR and WVTR. The OTR values, after lamination, in glassine paper and in specialization paper are extremely low (<0.1 ml/m²·day) and are at least one order of magnitude better from those of the structures without the material blend layer.

Thus, it is clear that the material blend used for making a metallized film of the invention must comprise material combinations that are stable in a suspension form, homogeneous, form a continuous, homogeneous film, upon drying, have a viscosity of 100-3500 cP, or below 1000 cP, to allow application in industrial units, and which can endow substrates with a smoothened surface, blocking pores which may be present.

1.-63.l (canceled)

64. A metalized film comprising or consisting of a film of a material blend, a metal surface and optionally a substrate, wherein the material blend film comprises at least one cellulose material and/or at least one wax and one or more additional additives optionally selected from carbohydrates, crosslinking agents, polymers, natural additives, minerals, surfactants, and nanoparticles.

65. The film according to claim 64, wherein the material blend comprises at least one cellulose material, and/or at least one wax.

66. The film according to claim 64, being metalized with a thin metal film, wherein metallization is achieved by vapor-depositing a metal thin film on a surface of the film of the material blend.

67. The film according to claim 64, the film comprising a cellulose material and/or a wax material layered with a thin metal film having a thickness of between 500 Å (Angstrom) and 100 nm.

68. The film according to claim 64, wherein the film of the material blend comprises at least one additive selected from carbohydrates, crosslinking agents, polymers, natural additives, minerals, surfactants, and nanoparticles.

69. The film according to claim 68, wherein the additive is at least one carbohydrate, optionally selected from starch, dextrin, cyclodextrin, maltodextrin, pectin, hemicellulose, sorbitol, and glycogen; or wherein the additive is at least one crosslinking agent, optionally selected from poly acrylic acid (PAA), polyethyleneimine (PEI), polyurethanes, alkenyl succinic anhydride (ASA), and alkyl ketene dimer (AKD), or wherein the additive is a natural additive, optionally selected from lignin, protein, chitosan, amino acid, lipid, gelatin, and alginate, or wherein the additive is at least one mineral material, optionally selected from clay, talc, gypsum, calcite, kaolin, aluminum silicate, illite, vermiculite, smectite, chlorite, and halloysite, or the additive is at least one surfactant, optionally selected from anionic surfactants, cationic surfactants, zwitterionic surfactants, non-ionic surfactants, sulfate based-surfactants, sulfonate based-surfactants, phosphate based-surfactants, carboxylate based-surfactants, anti-foam materials, ethoxylates based-surfactants, fatty acid ester based-surfactants, glycerol based-surfactants, sorbitol based-surfactants, and alkyl polyglycoside, or wherein the additive is at least one type of nanoparticles.

70. The film according to claim 64, wherein the film of the blend material comprises ethylene vinyl acetate (EVA) or comprises latex or comprises a thermoplastic polymer or comprises an epoxide.

71. The film according to claim 64, wherein the at least one cellulose material is selected from crystalline nanocellulose (CNC), nanofibrillar cellulose (NFC), microfibrillar cellulose (MFC), microcrystalline cellulose (MCC), cellulose nitrate, cellulose ester, cellulose acetate, ethyl cellulose, methyl cellulose, hydroxypropyl cellulose (HPC), hydroxyethyl cellulose (HEC), carboxymethyl cellulose (CMC), hydroxypropyl methylcellulose (HPMC), ethylhydroxyethyl cellulose (EHEC), methyl ethyl hydroxyethyl cellulose (MEHEC), or modified or oxidized forms thereof.

72. The film according to claim 64, the film consisting of
a substrate,
the film of a blend material comprising a cellulose material and/or a wax material and at least one additive, and
the metal film.

73. The film according to claim 72, the film consisting of
a substrate,
the film of a blend material comprising a cellulose material and at least one additive, and
the metal film.

74. The film according to claim 72, the film consisting of
a substrate,
the film of a blend material comprising a wax material and at least one additive, and
the metal film.

75. The film according to claim 72, the film consisting of
a substrate,
the film of a blend material comprising a cellulose material and a wax material and at least one additive, and
the metal film.

76. The film according to claim 64, wherein the film of the blend material comprising or consisting of:
(1) at least one cellulose-based material, and at least one additive selected from carbohydrates, crosslinking agents, polymers, natural additives, minerals, surfactants, nanoparticles; or
(2) at least one wax-based material, and at least one additive selected from carbohydrates, crosslinking agents, polymers, natural additives, minerals, surfactants, nanoparticles; or
(3) at least one cellulose-based material, at least one wax-based material, and at least one additive selected from carbohydrates, crosslinking agents, polymers, natural additives, minerals, surfactants, nanoparticles; or
(4) at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof, and at least one wax selected from carnauba wax, vegetable wax, beeswax, soy wax, coconut wax, Candelilla wax, and at least one modified wax, and at least one additive selected from carbohydrates, crosslinking agents, polymers, natural additives, minerals, surfactants, nanoparticles; or
(5) crystalline nanocellulose (CNC), and at least one wax selected from carnauba wax, vegetable wax, beeswax, soy wax, coconut wax, Candelilla wax, and at least one modified wax, and at least one additive selected from carbohydrates, crosslinking agents, polymers, natural additives, minerals, surfactants, nanoparticles; or
(6) nanofibrillar cellulose (NFC), and at least one wax selected from carnauba wax, vegetable wax, beeswax, soy wax, coconut wax, Candelilla wax, and at least one modified wax, and at least one additive selected from carbohydrates, crosslinking agents, polymers, natural additives, minerals, surfactants, nanoparticles; or
(7) microfibrillar cellulose (MFC), and at least one wax selected from carnauba wax, vegetable wax, beeswax, soy wax, coconut wax, Candelilla wax, and at least one modified wax, and at least one additive selected from carbohydrates, crosslinking agents, polymers, natural additives, minerals, surfactants, nanoparticles; or
(8) microcrystalline cellulose (MCC), and at least one wax selected from carnauba wax, vegetable wax, beeswax, soy wax, coconut wax, Candelilla wax, and at least one modified wax, and at least one additive selected from carbohydrates, crosslinking agents, polymers, natural additives, minerals, surfactants, nanoparticles; or
(9) CMC, and at least one wax selected from carnauba wax, vegetable wax, beeswax, soy wax, coconut wax, Candelilla wax, and at least one modified wax, and at least one additive selected from carbohydrates, crosslinking agents, polymers, natural additives, minerals, surfactants, nanoparticles; or
(10) HPMC, and at least one wax selected from carnauba wax, vegetable wax, beeswax, soy wax, coconut wax, Candelilla wax, and at least one modified wax, at least one additive selected from carbohydrates, crosslinking agents, polymers, natural additives, minerals, surfactants, nanoparticles; or
(11) crystalline nanocellulose (CNC) and/or nanofibrillar cellulose (NFC) and/or microfibrillar cellulose (MFC) and/or microcrystalline cellulose (MCC), and/or CMC, and/or HPMC, and at least one wax selected from carnauba wax, vegetable wax, beeswax, soy wax, coconut wax, Candelilla wax, and at least one modified wax, and at least one additive selected from carbohydrates, crosslinking agents, polymers, natural additives, minerals, surfactants, nanoparticles; or
(12) at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EEC, MEHEC, or modified or oxidized forms thereof, and carnauba wax, and at least one additive selected from carbohydrates, crosslinking agents, polymers, natural additives, minerals, surfactants, nanoparticles; or
(13) at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof, and vegetable wax, and at least one additive selected from carbohydrates, crosslinking agents, polymers, natural additives, minerals, surfactants, nanoparticles; or
(14) at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof, and beeswax, and at least one additive selected from carbohydrates, crosslinking agents, polymers, natural additives, minerals, surfactants, nanoparticles; or
(15) at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof, and Candelilla wax, and at least one modified wax, and at least one additive selected from carbohydrates, crosslinking agents, polymers, natural additives, minerals, surfactants, nanoparticles; or
(16) at least one cellulose material selected from crystalline nanocellulose (CNC), nanofibrillar cellulose (NFC), microfibrillar cellulose (MFC), or microcrystalline cellulose (MCC), cellulose nitrate, cellulose ester, cellulose acetate, ethyl cellulose, methyl cellulose, HPC, HEC, CMC, HPMC, EHEC, MEHEC, or modified or oxidized forms thereof, and at least one modified wax, and at least one additive selected from carbohydrates, crosslinking agents, polymers, natural additives, minerals, surfactants, nanoparticles; or
(17) crystalline nanocellulose (CNC), and/or CMC, and/or HPMC, and at least one additive selected from carbohydrates, crosslinking agents, polymers, natural additives, minerals, surfactants, nanoparticles; or
(18) crystalline nanocellulose (CNC), and/or CMC, and/or HPMC, and at least one additive selected from carbohydrates, crosslinking agents and polymers; or
(19) crystalline nanocellulose (CNC), and/or CMC, and/or HPMC, and/or MFC, and/or NFC, and at least one additive selected from carbohydrates, crosslinking agents, polymers, natural additives, minerals, surfactants, nanoparticles; or
(20) at least one wax or modified wax, and at least one additive selected from carbohydrates, crosslinking agents, polymers, natural additives, minerals, surfactants, nanoparticles; or
(21) at least one modified wax, and at least one additive selected from carbohydrates, crosslinking agents, polymers, natural additives, minerals, surfactants, nanoparticles; or
(22) at least two wax or modified wax materials, and at least one additive selected from carbohydrates, crosslinking agents, polymers, natural additives, minerals, surfactants, nanoparticles; or
(23) Starch, PVOH, CNC, HPMC and/or CMC; or
(24) Clay, PVOH, and CNC; or
(25) Starch, PVOH and CNC; or
(26) Starch, PVOH, CNC and Lignin; or
(27) Starch, PVOH, MFC and/or NFC, HPMC and/or CMC; or
(28) Wax and at least one surfactant; or
(29) Wax, latex and at least one surfactant; or
(30) Modified wax, latex and at least one surfactant; or
(31) Wax, modified wax, latex and at least one surfactant; or
(32) Wax, modified wax, an at least one surfactant; or
(33) Starch, PVOH, CNC, HPMC and/or CMC, modified wax and latex; or
(34) Starch (4.1-16.5 wt %), PVOH (5-15 wt %), CNC (0.1-5 wt %), HPMC and/or CMC (0.1-0.5 wt %); or
(35) Clay (4.2-13 wt %), PVOH (5-12 wt %), CNC (0.1-5 wt %); or
(36) Starch (5-14.5 wt %), PVOH (4.5-15.5 wt %), CNC (0.01-5 wt %); or
(37) Starch (4.5-15 wt %), PVOH (7-14.5 wt %), CNC (0.1-4 wt %), Lignin (7.3-13.1 wt %); or
(38) Starch (5.6-14.5 wt %), PVOH (6.5-14.2 wt %), MFC and/or NFC (0.1-5 wt %), HPMC and/or CMC (0.1-0.5 wt %); or
(39) Wax (2-30 wt %), surfactant (0.1-20 wt %); or
(40) Wax (2-22 wt %), Latex (2-30 wt %), surfactant (0.1-20 wt %); or
(41) Modified wax (1-25 wt %), Latex (2-30 wt %), surfactant (0.1-20 wt %); or
(42) Wax (1.5-20 wt %), modified wax (1-20 wt %), Latex (2-30 wt %), surfactant (0.1-20 wt %); or
(43) Wax (1.5-22 wt %), modified wax (1-20 wt %), surfactant (0.1-20 wt %); or
(44) Starch (1.5-9.5 wt %), PVOH (1.5-9.2 wt %), CNC (0.1-1.3 wt %), HPMC and/or CMC (0.1-1 wt %), modified wax and Latex (combined, 4.5-30.3 wt %).

77. A barrier for oxygen or water vapor, the barrier being in a form of a metalized film derived from a formulation comprising at least one wax or modified wax, and at least one additive selected from carbohydrates, crosslinking agents, polymers, natural additives, minerals, surfactants, nanoparticles; or at least one modified wax, and at least one additive selected from carbohydrates, crosslinking agents, polymers, natural additives, minerals, surfactants, nanoparticles; or at least two wax or modified wax materials, and at least one additive selected from carbohydrates, crosslinking agents, polymers, natural additives, minerals, surfactants, nanoparticles; or Wax and at least one surfactant; or Wax, latex and at least one surfactant; or Modified wax, latex and at least one surfactant; or Wax, modified wax, latex and at least one surfactant; or Wax, modified wax, an at least one surfactant; or Wax (2-30 wt %), surfactant (0.1-20 wt %); or Wax (2-22 wt %), Latex (2-30 wt %), surfactant (0.1-20 wt %); or Modified wax (1-25 wt %), Latex (2-30 wt %), surfactant (0.1-20 wt %); or Wax (1.5-20 wt %), modified wax (1-20 wt %), Latex (2-30 wt %), surfactant (0.1-20 wt %); or Wax (1.5-22 wt %), modified wax (1-20 wt %), surfactant (0.1-20 wt %); or Starch (1.5-9.5 wt %), PVOH (1.5-9.2 wt %), CNC (0.1-1.3 wt %), HPMC and/or CMC (0.1-1 wt %), modified wax and Latex (combined in an amount of 4.5-30.3 wt %).

78. A metalized film consisting a film of a material blend and a metal surface, wherein the material blend film comprises at least one cellulose material and/or at least one wax and one or more additional additives selected from carbohydrates, crosslinking agents, polymers, natural additives, minerals, surfactants, and nanoparticles.
